(19) United States
(12) Patent Application Publication
(10) Pub. No.: US 2025/0331352 A1
(43) Pub. Date: Oct. 23, 2025

(54) DISPLAY DEVICE AND ELECTRONIC DEVICE COMPRISING DISPLAY DEVICE

(71) Applicant: Samsung Display Co., Ltd., Yongin-Si (KR)

(72) Inventors: Ki Nyeng KANG, Yongin-si (KR); Ki Beom LEE, Yongin-si (KR); Keun Kyu SONG, Yongin-si (KR)

(21) Appl. No.: 18/983,345

(22) Filed: Dec. 17, 2024

(30) Foreign Application Priority Data
Apr. 22, 2024 (KR) 10-2024-0053392

(51) Int. Cl. H10H 29/49; G06F 3/041; G06F 3/044; H10H 29/37

(52) U.S. Cl. CPC H10H 29/49; G06F 3/0412; G06F 3/0446; H10H 29/37

(57) ABSTRACT

A display device includes a display part configured to emit light, and a sensor part disposed on the display part and including sensing electrodes. The display part includes a first electrode and a second electrode spaced apart from each other, a light emitting element disposed between the first electrode and the second electrode in a plan view and including a first end and a second end, a first connection electrode electrically connected to the first end, a second connection electrode electrically connected to the second end, a shielding layer overlapping the light emitting element in a plan view, and a transparent planarization layer disposed on the shielding layer.

This application claims priority to Korean Patent Application No. 10-2024-0053392, filed on Apr. 22, 2024 in the Korean Intellectual Property Office, the disclosure of which is incorporated by reference herein in its entirety.

### BACKGROUND

### 1. FIELD

The disclosure relates to a display device and an electronic device comprising the display device.

### 2. DESCRIPTION OF THE RELATED ART

In recent years, as interest in information display is increasing, research and development for a display device are continuously being conducted.

The display device may include a sensor configured to perform an operation of interacting with a user. The display device may further include a line or the like for forming the sensor so that the sensor is formed in the display device.

Accordingly, a risk that may occur due to an electrical signal formed when the sensor operates is required to be reduced.

### SUMMARY

An aspect of the disclosure is to provide a display device and an electronic device comprising the display device in which a range of a dead space may be reduced.

As aspect of the disclosure is to provide a display device and an electronic device comprising the display device in which reliability for an electrical signal is reconsidered by reducing a parasitic capacitance in the display device.

As aspect of the disclosure is to provide a display device and an electronic device comprising the display device with improved process convenience.

According to an embodiment of the disclosure, a display device may include a display part configured to emit light, and a sensor part disposed on the display part and including sensing electrodes. The display part may include a first electrode and a second electrode spaced apart from each other, a light emitting element disposed between the first electrode and the second electrode in a plan view and including a first end and a second end, a first connection electrode electrically connected to the first end, a second connection electrode electrically connected to the second end, a shielding layer overlapping the light emitting element in a plan view, and a transparent planarization layer disposed on the shielding layer.

According to an embodiment, the shielding layer and the transparent planarization layer may be disposed between the light emitting element and the sensor part.

According to an embodiment, the display part may further include a display base layer and a bank protruding in a thickness direction of the display base layer. The shielding layer may be disposed in an area surrounded by the bank.

According to an embodiment, the display device may include a display area and a non-display area surrounding at least a portion of the display area. The shielding layer may be disposed entirely in an entire surface of the display area.

According to an embodiment, the shielding layer may be electrically connected to the second connection electrode.

According to an embodiment, the display part may further include a first power line supplying first power and a second power line supplying second power forming a voltage lower than a voltage of the first power. The second connection electrode may be electrically connected to the second power line.

According to an embodiment, the shielding layer may be electrically separated from the first connection electrode.

According to an embodiment, the shielding layer may include a transparent conductive material.

According to an embodiment, the transparent planarization layer may include an acryl-based resin.

According to an embodiment, the transparent planarization layer may be manufactured based on an acryl-based resin composition. The acryl-based resin composition may include an acrylic resin, an acrylic monomer, a photoinitiator, and a solvent. The acrylic resin may be contained in an amount of 6% by weight to 11% by weight based on the entire acryl-based resin composition. The acrylic monomer may be contained in an amount of 2% by weight to 15% by weight based on the entire acryl-based resin composition. The photoinitiator may be contained in an amount of 2% by weight to 15% by weight based on the entire acryl-based resin composition. The solvent may be contained in an amount of 71% by weight to 91% by weight based on the entire acryl-based resin composition.

According to an embodiment, the acrylic resin may have a weight average molecular weight of 5000 to 25000. The acrylic monomer may include one or more of cyclic trimethylolpropane formal acrylate, tris(2-hydroxyethyl) isocyanurate triacrylate, and ethoxylated flrorene type diacrylate. The photoinitiator may include one or more of 2,4,6-trimethylbenzoyl-diphenyl-phosphineoxide and 4-(dimethylamino)benzophenone. The solvent may include one or more of Methyl 3-methoxypropionate and propylene glycol methyl ether acetate.

According to an embodiment, the display device may include a display area and a non-display area surrounding at least a portion of the display area. The display part may further include a trace line electrically connected to at least a portion of the sensing electrodes through a contact member of which at least a portion passes through the transparent planarization layer. At least a portion of the trace line may be disposed in the display area.

According to an embodiment, the shielding layer and the trace line may include a same material.

According to an embodiment, the display part may further include a display base layer and a bank protruding in a thickness direction of the display base layer. The trace line may not overlap the bank in a plan view.

According to an embodiment, the display part may further include a backplane conductive layer disposed below the light emitting element. The backplane conductive layer may be electrically connected to the trace line.

According to an embodiment, the display device may further include color filters disposed on the sensor part and transmitting light of one color. The light emitting element may include an inorganic material.

According to an embodiment, the display device may include a first sub-pixel area where light of a first color is provided; a second sub-pixel area where light of a second color is provided; and a third sub-pixel area where light of a third color is provided. The display device may further include a plurality of light emitting elements including the light emitting element. The plurality of light emitting elements may include a first light emitting element disposed in the first sub-pixel area and providing the light of the first color, a second light emitting element disposed in the second sub-pixel area and providing the light of the second color, and a third light emitting element disposed in the third sub-pixel area and providing the light of the third color.

According to an embodiment of the disclosure, a display device may include a display area and a non-display area surrounding at least a portion of the display area, a display part including a first electrode, a second electrode, a light emitting element disposed between the first electrode and the second electrode in a plan view, and a trace line, and a sensor part disposed on the display part and including sensing electrodes. At least a portion of the sensing electrodes may be electrically connected to the trace line. The trace line may be disposed in the display area.

According to an embodiment of the disclosure, an electronic device may comprise: a processor configured to provide input image data; a display device configured to display an image based on the input image data, the display device including sub-pixel areas; and a power supply configured to supply power to the display device. The display device may comprise: a display part configured to emit light; and a sensor part disposed on the display part and including sensing electrodes. The display part may comprise: a first electrode and a second electrode spaced apart from each other; a light emitting element disposed between the first electrode and the second electrode in a plan view and including a first end and a second end; a first connection electrode electrically connected to the first end; a second connection electrode electrically connected to the second end; a shielding layer overlapping the light emitting element in a plan view; and a transparent planarization layer disposed on the shielding layer.

According to an embodiment of the disclosure, a display device and an electronic device comprising the display device in which a range of a dead space may be reduced may be provided.

According to an embodiment of the disclosure, a display device and an electronic device comprising the display device in which reliability for an electrical signal is reconsidered by reducing a parasitic capacitance in the display device may be provided.

According to an embodiment of the disclosure, a display device and an electronic device comprising the display device with improved process convenience may be provided.

### BRIEF DESCRIPTION OF THE DRAWINGS

The above and other features of the disclosure will become more apparent by describing in further detail embodiments thereof with reference to the accompanying drawings.

FIG. 1 is a diagram illustrating a display device according to an embodiment.

FIG. 2 is a schematic plan view illustrating a sensor part according to an embodiment.

FIG. 3 is a schematic cross-sectional view illustrating a stack structure of a display device according to an embodiment.

FIG. 4 is a schematic plan view illustrating a display part according to an embodiment.

FIG. 5 is a schematic perspective view illustrating a light emitting element according to an embodiment.

FIG. 6 is a schematic cross-sectional view illustrating a light emitting element according to an embodiment.

FIG. 7 is a schematic cross-sectional view illustrating a sensor part according to an embodiment.

FIG. 8 is a schematic plan view illustrating sensing electrodes according to an embodiment.

FIG. 9 is a schematic cross-sectional view illustrating a sensor part according to an embodiment.

FIG. 10 is a schematic cross-sectional view illustrating a display device according to an embodiment.

FIG. 11 is a schematic cross-sectional view illustrating an electrical connection structure for a trace line according to an embodiment.

FIG. 12 is a schematic cross-sectional view illustrating a display device according to an embodiment.

FIG. 13 is a schematic block diagram illustrating an electronic device including a display device in accordance with an embodiment.

FIG. 14 is a schematic diagram illustrating an example where the electronic device of FIG. 13 is implemented as a smartphone.

FIG. 15 is a schematic diagram illustrating an example where the electronic device of

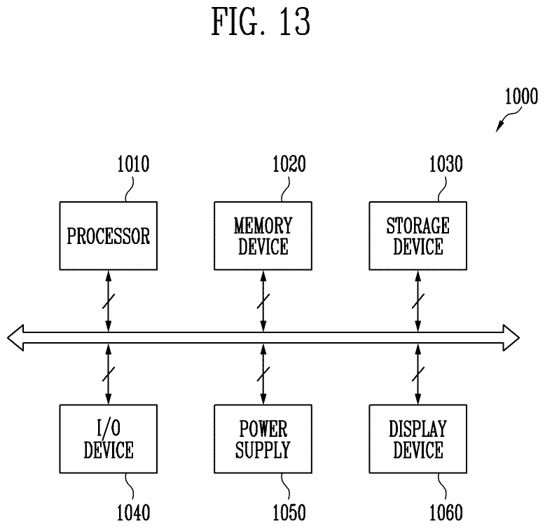

FIG. 13 is implemented as a tablet computer.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a display device and an electronic device comprising the display device. Hereinafter, a display device and an electronic device comprising the display device according to an embodiment is described with reference to the accompanying drawings.

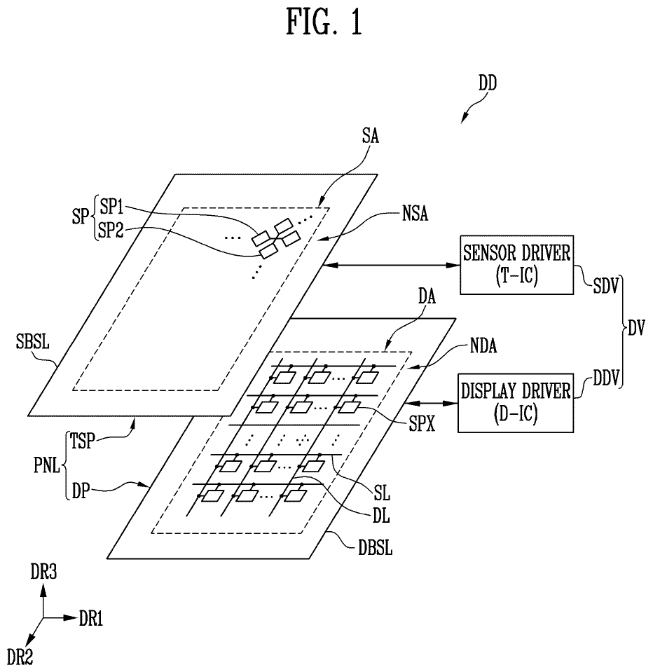

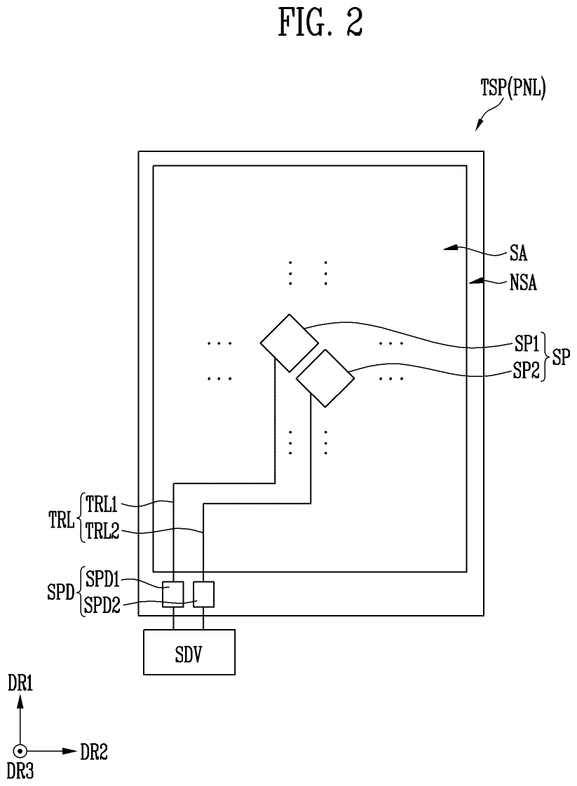

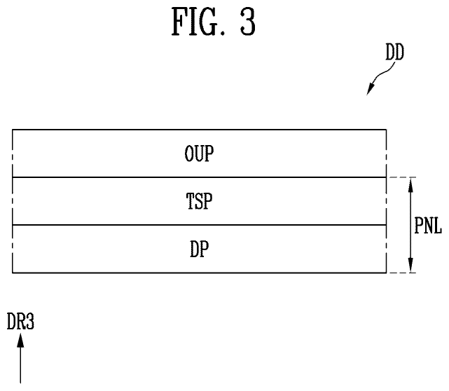

FIG. 1 is a diagram illustrating a display device DD according to an embodiment. FIG. 2 is a schematic plan view illustrating a sensor part TSP according to an embodiment. FIG. 3 is a schematic cross-sectional view illustrating a stack structure of the display device DD according to an embodiment.

Referring to FIGS. 1 to 3, the display device DD is configured to provide (or emit) light. The display device DD may include a panel PNL and a driving circuit part DV for driving the panel PNL. The display device DD may further include an outer part OUP.

The panel PNL may include a display part DP for displaying an image and the sensor part TSP capable of sensing a user input (for example, a touch input). The display part DP may be referred to as a display panel or a display layer. The sensor part TSP may be referred to as a sensing panel or a sensor layer.

The panel PNL may include sub-pixels SPX and sensing electrodes SP. According to an embodiment, the sub-pixels SPX may display an image in a display frame period unit. The sensing electrodes SP may sense an input (for example, a touch input) of a user in a sensing frame period unit. A sensing frame period and a display frame period may be independent of each other or may be different from each other. The sensing frame period and the display frame period may be synchronized or asynchronized with each other.

The sensor part TSP including the sensing electrodes SP may obtain information on the touch input of the user. According to an embodiment (for example, a mutual capacitance method), the sensing electrodes SP may include a first sensing electrode SP1 providing a first sensing signal and a second sensing electrode SP2 providing a second sensing signal. According to an embodiment, the first sensing electrode SP1 may be a Tx (transmitter) pattern electrode, and the second sensing electrode SP2 may be an Rx (receiver) pattern electrode. The information on the touch input (or a touch event) may mean information including a position or the like of a touch that the user wants to provide.

However, the disclosure is not limited thereto. For example, according to an embodiment (for example, a self-capacitance method), the sensing electrodes SP may be configured of one type of sensing electrodes without distinction between the first sensing electrode SP1 and the second sensing electrode SP2.

The driving circuit part DV may include a display driver (D-IC) DDV for driving the display part DP and a sensor driver (T-IC) SDV for driving the sensor part TSP.

The display part DP may include a display base layer DBSL and the sub-pixels SPX provided on the display base layer DBSL. The sub-pixels SPX may be disposed in a display area DA.

The display base layer DBSL (or the display device DD) may include the display area DA in which an image is displayed and a non-display area NDA outside the display area DA. According to an embodiment, the display area DA may be disposed in a central area of the display part DP, and the non-display area NDA may be disposed adjacent to a periphery of the display area DA.

The display base layer DBSL may be a base substrate or a base member for supporting the display device DD. The base layer may be a rigid substrate of a glass material. In an embodiment, the base layer may be a flexible substrate of which bending, folding, rolling, or the like is possible. In this case, the base layer may include an insulating material such as a polymer resin such as polyimide. However, the disclosure is not particularly limited thereto.

Scan lines SL and data lines DL, and the sub-pixels SPX connected to the scan lines SL and the data lines DL may be disposed in the display area DA. The sub-pixels SPX may be configured to be selected by a scan signal of a turn-on level supplied from the scan lines SL, receive a data signal from the data lines DL, and emit light of a luminance corresponding to the data signal. Accordingly, an image corresponding to the data signal is displayed in the display area DA. However, in the disclosure, a structure, a driving method, and the like of the sub-pixels SPX are not particularly limited.

Various lines and/or built-in circuit units connected to the sub-pixels SPX of the display area NDA may be disposed in the non-display area NDA. For example, a plurality of lines for supplying various power and control signals to the display area DA may be disposed in the non-display area NDA.

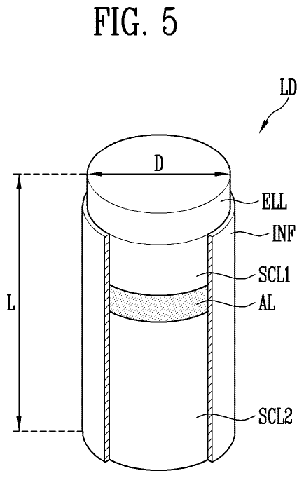

The display part DP may output visual information (for example, an image). According to an embodiment, the display part DP may include a light emitting element LD (FIG. 5) including an inorganic material.

The sensor part TSP includes a sensor base layer SBSL and a plurality of sensing electrodes SP formed on the sensor base layer SBSL. The sensing electrodes SP may be disposed in a sensing area SA on the sensor base layer SBSL. The panel PNL may further include a trace line TRL and a sensing pad SPD.

The sensor base layer SBSL (or the display device DD) may include the sensing area SA where a touch input or the like may be sensed, and a non-sensing area NSA around the sensing area SA. According to an embodiment, the sensing area SA may be disposed to overlap at least one area of the display area DA. For example, the sensing area SA may be set as an area corresponding to the display area DA (for example, an area overlapped with the display area DA), and the non-sensing area NSA may be set as an area corresponding to the non-display area NDA (for example, an area overlapped with the non-display area NDA). In this case, when the touch input or the like is provided on the display area DA, the touch input may be detected through the sensor part TSP.

The sensor base layer SBSL may include one or more insulating layers. For example, one or more insulating layers for forming the sensor base layer SBSL may be disposed on the display part DP to form a base for forming the sensing electrodes SP. However, an example for forming the sensor base layer SBSL is not particularly limited.

The sensing area SA is set as an area capable of responding to the touch input (that is, an active area of a sensor). To this end, the sensing electrodes SP for sensing the touch input or the like may be disposed in the sensing area SA.

The sensor part TSP may obtain information on an input provided from the user. The sensor part TSP may recognize the touch input. The sensor part TSP may recognize the touch input using a capacitive sensing method. The sensor part TSP may sense the touch input using a mutual capacitance method or may sense the touch input using a self-capacitance method.

According to an embodiment, each of the first sensing electrodes SP1 may extend in a first direction DR1. The first sensing electrodes SP1 may be arranged in a second direction DR2. The second direction DR2 may be different from the first direction DR1. For example, the second direction DR2 may be a direction perpendicular to the first direction DR1.

According to an embodiment, each of the second sensing electrodes SP2 may extend in the second direction DR2. The second sensing electrodes SP2 may be arranged in the first direction DR1.

According to an embodiment, the first sensing electrodes SP1 and the second sensing electrodes SP2 may have the same (for example, substantially the same) shape. For example, the first sensing electrodes SP1 which are Tx patterns and the second sensing electrodes SP2 which are Rx patterns may have a corresponding shape (for example, substantially the same shape), and thus sensing performance of the touch event may be uniformly set within the sensing area SA.

Sensing lines for electrically connecting the sensing electrodes SP to a sensor driver SDV and the like may be disposed in the non-sensing area NSA of the sensor part TSP.

The driving circuit part DV may include the display driver DDV for driving the display part DP and the sensor driver SDV for driving the sensor part TSP.

The display driver DDV is configured to be electrically connected to the display part DP to drive the sub-pixels SPX. The sensor driver SDV is configured to be electrically connected to the sensor part TSP to drive the sensor part TSP.

The trace line TRL may overlap the display area DA in a plan view. The trace line TRL may electrically connect a sensing electrode SP and a sensor pad SPD.

The trace line TRL may include a first trace line TRL1 and a second trace line TRL2. The first trace line TRL1 may electrically connect the first sensing electrode SP1 and a first sensor pad SPD1. The second trace line TRL2 may electrically connect the second sensing electrode SP2 and a second sensor pad SPD2.

According to an embodiment, at least a portion of the trace line TRL may be disposed in the sensing area SA, and the trace line TRL may be patterned across the sensing area SA. Experimentally, when the trace line TRL is disposed in the non-sensing area NSA, a risk that a dead space is excessively increased may occur. However, according to an embodiment, since the trace line TRL is patterned across the sensing area SA, a range of the dead space may be substantially reduced.

The sensor pad SPD may be disposed in the non-sensing area NSA. The sensor pad SPD may be electrically connected to the sensor driver SDV. Accordingly, the sensing electrode SP may be electrically connected to the sensor driver SDV through the trace line TRL and the sensor pad SPD.

The sensor pad SPD may include the first sensor pad SPD1 and the second sensor pad SPD2. The first sensor pad SPD1 may be electrically connected to the first sensing electrode SP1. The second sensor pad SPD2 may be electrically connected to the second sensing electrode SP2.

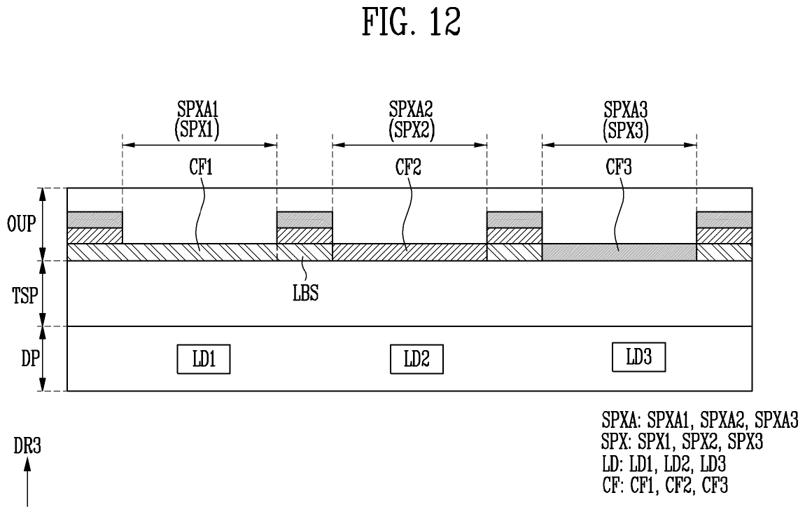

The outer part OUP may be disposed generally on an outer side of the display device DD. The outer part OUP may be disposed on the sensor part TSP. Light provided from the display part DP may pass through the outer part OUP and may be output to an outside. According to an embodiment, the outer part OUP may include color filters CF (refer to FIG. 12). According to an embodiment, the outer part OUP may further include a window.

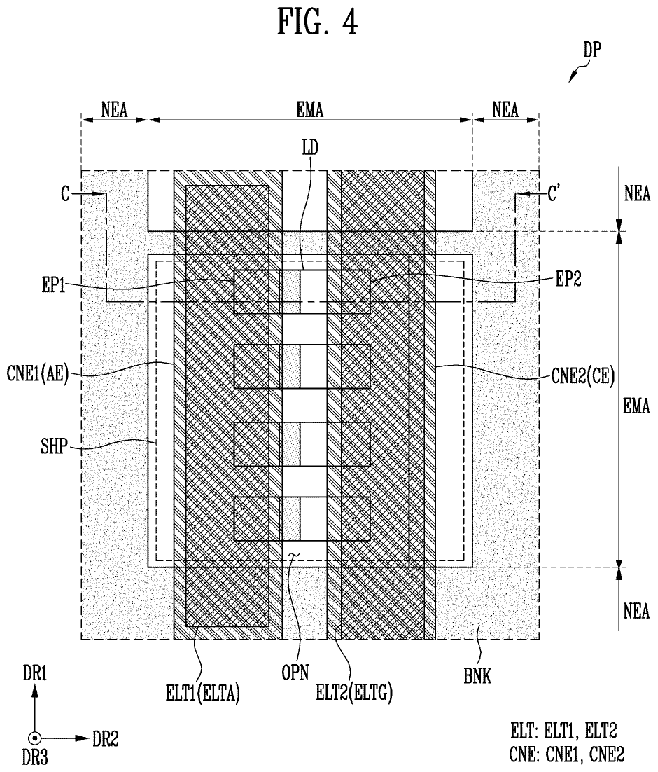

With reference to FIGS. 4 to 6, the light emitting element LD and the display part DP including the light emitting element LD according to an embodiment are described.

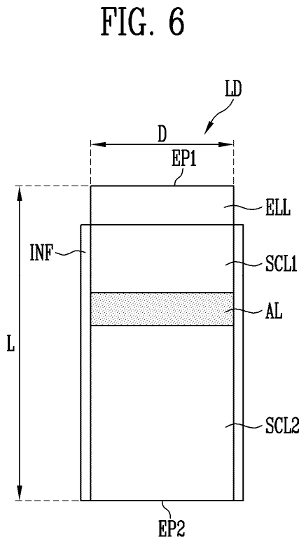

FIG. 4 is a schematic plan view illustrating the display part DP according to an embodiment. FIG. 5 is a schematic perspective view illustrating the light emitting element LD according to an embodiment. FIG. 6 is a schematic cross-sectional view illustrating the light emitting element LD according to an embodiment.

Referring to FIGS. 4 to 6, the display part DP includes the light emitting element LD.

The light emitting element LD is configured to emit light. The light emitting element LD may include a first semiconductor layer SCL1, a second semiconductor layer SCL2, and an active layer AL disposed between the first semiconductor layer SCL1 and the second semiconductor layer SCL2. According to an embodiment, the first semiconductor layer SCL1, the active layer AL, and the second semiconductor layer SCL2 may be sequentially stacked along a length L direction of the light emitting element LD. According to an embodiment, the light emitting element LD may further include an electrode layer ELL and an insulating film INF.

The light emitting element LD may have various shapes. For example, the light emitting element LD may have a column shape extending in one direction. The column shape may include a rod-like shape or a bar-like shape long in the length L direction (for example, an aspect ratio is greater than 1), such as a circular column or a polygonal column, and a cross-sectional shape thereof is not particularly limited.

The light emitting element LD may have a first end EP1 and a second end EP2. According to an embodiment, the first semiconductor layer SCL1 may be adjacent to the first end EP1 of the light emitting element LD, and the second semiconductor layer SCL2 may be adjacent to the second end EP2. According to an embodiment, an electrode layer ELL may be adjacent to the first end EP1.

The light emitting element LD may be manufactured by etching sequentially stacked semiconductor layers. The light emitting element LD may have a size of a nano scale to a micro scale. For example, each of a diameter D (or a width) of the light emitting element LD and the length L of the light emitting element LD may have a nano scale to a micro scale. However, the disclosure is not limited thereto.

The first semiconductor layer SCL1 may include a first conductivity type semiconductor. The first semiconductor layer SCL1 may be disposed on the active layer AL and may include a semiconductor layer of a type different from that of the second semiconductor layer SCL2. For example, the first semiconductor layer SCL1 may include a P-type semiconductor layer. For example, the first semiconductor layer SCL1 may include one or more semiconductor materials selected from a group of InAlGaN, GaN, AlGaN, InGaN, AlN, and InN, and may include a P-type semiconductor layer doped with a first conductivity type dopant such as Ga, B, and Mg. However, the disclosure is not limited to the above-described example. The first semiconductor layer SCL1 may include various materials.

The active layer AL may be disposed between the first semiconductor layer SCL1 and the second semiconductor layer SCL2. The active layer AL may include a single-quantum well or multi-quantum well structure. A position of the active layer AL is not limited to a specific example and may be variously changed according to a type of the light emitting element LD.

A clad layer doped with a conductive dopant may be formed on one side and/or another side of the active layer AL. For example, the clad layer may include one or more of AlGaN and InAlGaN. However, the disclosure is not limited to the above-described example.

The second semiconductor layer SCL2 may include a second conductivity type semiconductor. The second semiconductor layer SCL2 may be disposed on the active layer AL and may include a semiconductor layer of a type different from that of the first semiconductor layer SCL1. For example, the second semiconductor layer SCL2 may include an N-type semiconductor layer. For example, the second semiconductor layer SCL2 may include one or more selected from a group of InAlGaN, GaN, AlGaN, InGaN, AlN, and InN, and may include an N-type semiconductor layer doped with a second conductivity type dopant such as Si, Ge, and Sn. However, the disclosure is not limited to the above-described example. The second semiconductor layer SCL2 may include various materials.

When a voltage equal to or greater than a threshold voltage is applied to the first end EP1 and the second end EP2 of the light emitting element LD, an electron-hole pair may recombine with each other in the active layer AL, and the light emitting element LD may emit light. By controlling light emission of the light emitting element LD using such a principle, the light emitting element LD may be used as a light source in various devices.

The insulating film INF may be disposed on one surface of the light emitting element LD. The insulating film INF may surround an outer surface of the active layer AL, and may further surround a portion of each of the first semiconductor layer SCL1 and the second semiconductor layer SCL2. The insulating film INF may have a single layer or multiple layer structure.

The insulating film INF may expose the first end EP1 and the second end EP2 of the light emitting element LD having different polarities. For example, the insulating film INF may expose one end of each of the electrode layer ELL and the second semiconductor layer SCL2 adjacent to the first end EP1 and the second end EP2 of the light emitting element LD. The insulating film INF may ensure electrical stability of the light emitting element LD. In addition, the insulating film INF may minimize a surface defect of the light emitting element LD to improve lifespan and efficiency. In addition, when a plurality of light emitting elements LD are disposed in close to each other, the insulating film INF may prevent a short defect between the light emitting elements LD.

According to an embodiment, the insulating film INF may include at least one of a group of silicon oxide (SiOx), silicon nitride (SiNx), silicon oxynitride (SiOxNy), aluminum oxide (AlxOy), and titanium oxide (TiOx). However, the insulating film INF is not necessarily limited to the example described above in the disclosure.

The electrode layer ELL may be disposed on the first semiconductor layer SCL1. The electrode layer ELL may be adjacent to the first end EP1. The electrode layer ELL may be electrically connected to the first semiconductor layer SCL1. A portion of the electrode layer ELL may be exposed. For example, the insulating film INF may expose one surface of the electrode layer ELL. The electrode layer ELL may be exposed in an area corresponding to the first end EP1. According to an embodiment, a side surface of the electrode layer ELL may be exposed. For example, the insulating film INF may cover side surfaces of each of the first semiconductor layer SCL1, the active layer AL, and the second semiconductor layer SCL2, and may not cover at least a portion of the side surface of the electrode layer ELL. In this case, electrical connection to another configuration of the electrode layer ELL adjacent to the first end EP1 may be easy. According to an embodiment, the insulating film INF may expose a portion of the side surface of the first semiconductor layer SCL1 and/or the second semiconductor layer SCL2 as well as the side surface of the electrode layer ELL.

According to an embodiment, the electrode layer ELL may be an Ohmic contact electrode. However, the disclosure is not limited to the above-described example. For example, the electrode layer ELL may be a Schottky contact electrode.

According to an embodiment, the electrode layer ELL may include one or more of a group of chromium (Cr), titanium (Ti), aluminum (Al), gold (Au), nickel (Ni), an oxide thereof, and an alloy thereof. However, the disclosure is not limited to the above-described example. According to an embodiment, the electrode layer ELL may be substantially transparent. For example, the electrode layer ELL may include indium tin oxide (ITO). Accordingly, the electrode layer ELL may transmit emitted light.

A structure, a shape, or the like of the light emitting element LD is not limited to the above-described example, and the light emitting element LD may have various structures and shapes according to an embodiment. For example, the light emitting element LD may further include an additional electrode layer disposed on one surface of the second semiconductor layer SCL2 and adjacent to the second end EP2.

According to an embodiment, the display part DP (for example, the display device DD) may include an emission area EMA and a non-emission area NEA. The display part DP (for example, the display device DD) may further include a bank BNK, an electrode layer ELT, the light emitting element LD, and a connection electrode layer CNE. According to an embodiment, the display part DP may further include a shielding layer SHP.

The emission area EMA may overlap an opening OPN defined by the bank BNK in a plan view. The light emitting elements LD may be disposed in the emission area EMA. The light emitting elements LD may not be disposed in the non-emission area NEA.

The bank BNK may form (or provide) the opening OPN. For example, the bank BNK may have a shape protruding in a thickness direction (for example, a third direction DR3) of the base layer DBSL and may surround one area. According to an embodiment, an ink including the light emitting element LD may be supplied to the opening OPN defined by the bank BNK, and the light emitting element LD may be disposed in the opening OPN.

According to an embodiment, the bank BNK may include an organic material such as acrylic resin, epoxy resin, phenol resin, polyamide resin, polyimide resin, polyester resin, polyphenylenesulfide resin, or benzocyclobutene (BCB). However, the disclosure is not limited to the example described above.

The electrode layer ELT may include electrodes for aligning the light emitting element LD. The electrode layer ELT may be referred to as an alignment electrode layer. According to an embodiment, the electrode layer ELT may include a first electrode ELT1 and a second electrode ELT2. According to an embodiment, the first electrode ELT1 may be a first alignment electrode ELTA, and a second electrode ELT2 may be a second alignment electrode ELTG.

The light emitting element LD may be disposed (or aligned) on the electrode layer ELT. According to an embodiment, the light emitting element LD may be aligned between the first electrode ELT1 and the second electrode ELT2 in a plan view. The light emitting elements LD may form (or configure) a light emitting part.

According to an embodiment, the first electrode ELT1 and the second electrode ELT2 may be spaced apart from each other along the second direction DR2 in the emission area EMA. The first electrode ELT1 and the second electrode ELT2 may extend in the first direction DR1.

According to an embodiment, the first electrode ELT1, which is the first alignment electrode ELTA, may be an electrode to which an AC signal is supplied to align the light emitting elements LD. The first electrode ELT1 may be an electrode to which an anode signal is supplied so that the light emitting elements LD emit light. The second electrode ELT2, which is the second alignment electrode ELTG, may be an electrode to which a ground signal is supplied to align the light emitting elements LD. The second electrode ELT2 may be an electrode to which a cathode signal is supplied so that the light emitting elements LD emit light.

The first electrode ELT1 (or the first alignment electrode ELTA) and the second electrode ELT2 (or the second alignment electrode ELTG) may be supplied (or provided) with a first alignment signal and a second alignment signal, respectively, in a process step in which the light emitting elements LD are aligned. For example, the ink including the light emitting element LD may be supplied (or provided) to the opening OPN, the first alignment signal may be supplied to the first electrode ELT1, and the second alignment signal may be supplied to the second electrode ELT2. At this time, the first alignment signal and the second alignment signal may have different waveforms, potentials, and/or phases. For example, the first alignment signal may be an AC signal and the second alignment signal may be a ground signal. However, the disclosure is not limited to the above-described example. An electric field may be formed between (or on) the first electrode ELT1 and the second electrode ELT2, and the light emitting elements LD may be aligned between the first electrode ELT1 and the second electrode ELT2 based on the electric field. For example, the light emitting elements LD may be moved (or rotated) by force (for example, dielectrophoresis (DEP) force) according to the electric field, and may be aligned (or disposed) on the first alignment electrode ELTA and the second alignment electrode ELTG.

The light emitting element LD may emit light based on a provided electrical signal. For example, the light emitting element LD may provide the light based on a first electrical signal (for example, the anode signal) provided from a first connection electrode CNE1 and a second electrical signal (for example, the cathode signal) provided from a second connection electrode CNE2.

The first end EP1 of the light emitting element LD may be disposed adjacent to the first electrode ELT1, and the second end EP2 of the light emitting element LD may be disposed adjacent to the second electrode ELT2.

The light emitting element LD may be disposed in the opening OPN. The light emitting element LD may form the emission area. The emission area may include an area where the light emitting element LD is disposed.

The connection electrode layer CNE may be disposed on the first ends EP1 and the second ends EP2 of the light emitting elements LD. The first connection electrode CNE1 may be disposed on the first ends EP1 of the light emitting elements LD to be electrically connected to the first ends EP1 of the light emitting elements LD. The second connection electrode CNE2 may be disposed on the second ends EP2 of the light emitting elements LD to be electrically connected to the second ends EP2 of the light emitting elements LD.

According to an embodiment, the connection electrode layer CNE may include the first connection electrode CNE1 and the second connection electrode CNE2. The first connection electrode CNE1 may be the anode connection electrode AE, and the second connection electrode CNE2 may be the cathode connection electrode CE. According to an embodiment, the first connection electrode CNE1 may be electrically connected to the first electrode ELT1. The second connection electrode CNE2 may be electrically connected to the second electrode ELT2.

The shielding layer SHP may overlap the light emitting element LD in a plan view. The shielding layer SHP may shield the light emitting element LD. The shielding layer SHP may cover the light emitting element LD.

The shielding layer SHP may be referred to as a cover layer or a transparent cover layer.

According to an embodiment, the shielding layer SHP may include a conductive material. The shielding layer SHP may include a transparent conductive material. For example, the shielding layer SHP may include one or more of a group of indium tin oxide (ITO), indium zinc oxide (IZO), and indium tin zinc oxide (ITZO). However, the disclosure is not limited to the example described above.

In FIG. 4, a range where the shielding layer SHP is disposed is indicated by a dotted box. For example, the shielding layer SHP may be disposed in an area (for example, the opening OPN) surrounded by the bank BNK. Accordingly, the shielding layer SHP may include a plurality of shielding layers SHP disposed in the respective emission areas EMA. However, the disclosure is not limited thereto. For example, the shielding layer SHP may be formed throughout the display area DA. In this case, the shielding layer SHP may be a structure deposited on the entire surface in the display area DA. For example, the shielding layer SHP may be entirely formed on the entire surface in the display area DA. In addition, according to an embodiment, the shielding layer SHP may at least partially overlap the bank BNK in a plan view.

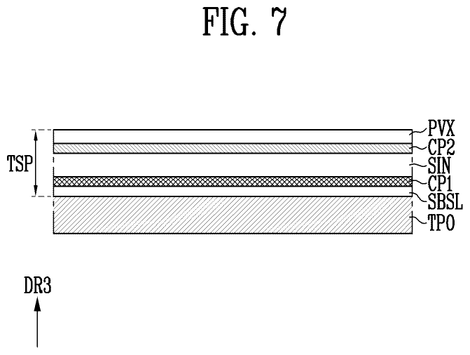

With reference to FIGS. 7 to 9, the sensor part TSP according to an embodiment is described.

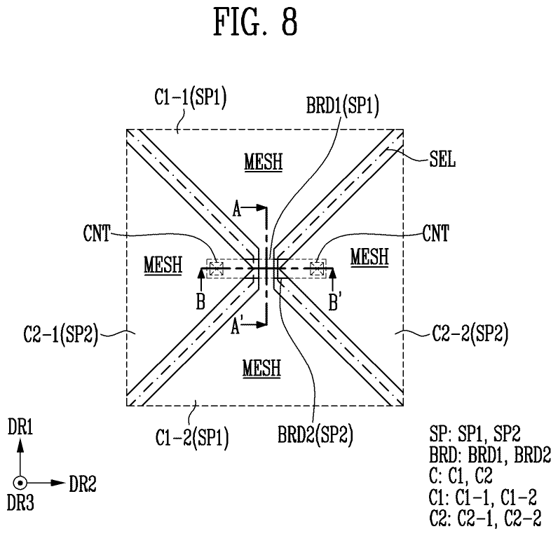

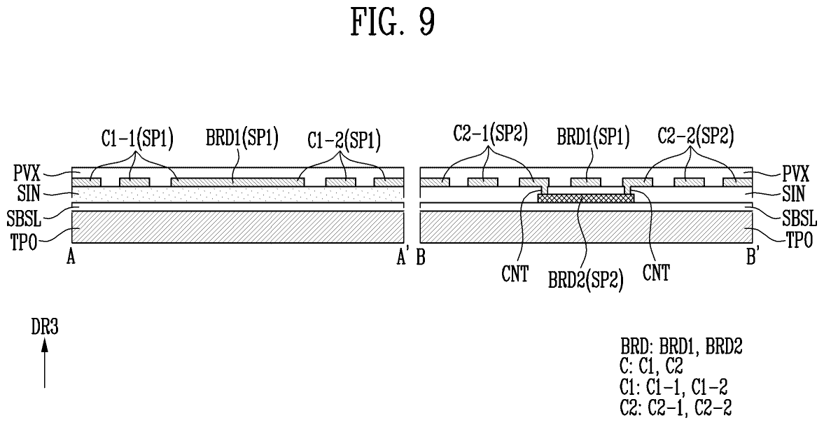

FIG. 7 is a schematic cross-sectional view illustrating the sensor part TSP according to an embodiment. FIG. 8 is a schematic plan view illustrating sensing electrodes SP according to an embodiment. FIG. 8 shows a schematic planar structure illustrating an area where the first sensing electrode SP1 and the second sensing electrode SP2 are adjacent to each other. FIG. 8 shows a planar structure of the first sensing electrode SP1 and the second sensing electrode SP2 each having one shape according to an embodiment. FIG. 9 is a schematic cross-sectional view illustrating the sensor part TSP according to an embodiment. FIG. 9 shows a schematic cross-sectional structure along A-A′ of FIG. 8 and a cross-sectional structure along B-B′ of FIG. 8.

Referring to FIGS. 7 to 9, the sensor part TSP may be disposed on a transparent planarization layer TPO. The sensor part TSP may include a sensor base layer SBSL, a first conductive pattern layer CP1, a sensor insulating layer SIN, a second conductive pattern layer CP2, and a protective layer PVX.

According to an embodiment, the first conductive pattern layer CP1 and the second conductive pattern layer CP2 may be patterned in one area to form the sensing electrodes SP. For example, a portion of the first conductive pattern layer CP1 may form the first sensing electrode SP1, and a portion of each of the first conductive pattern layer CP1 and the second conductive pattern layer CP2 may form the second sensing electrode SP2. In an embodiment, a portion of the second conductive pattern layer CP2 may form the first sensing electrode SP1, and a portion of each of the first conductive pattern layer CP1 and the second conductive pattern layer CP2 may form the second sensing electrode SP2. However, the disclosure is not limited thereto.

The sensor base layer SBSL may be disposed on the transparent planarization layer TPO. The sensor base layer SBSL may provide an area where the first conductive pattern layer CP1, the sensor insulating layer SIN, the second conductive pattern layer CP2, and the protective layer PVX are disposed.

The transparent planarization layer TPO may be a transparent planarization structure disposed on the light emitting element LD. Details regarding the transparent planarization layer TPO are described later.

The first conductive pattern layer CP1 may be disposed on the sensor base layer SBSL. The second conductive pattern layer CP2 may be disposed on the sensor insulating layer SIN. The first conductive pattern layer CP1 and the second conductive pattern layer CP2 may be spaced apart from each other with the sensor insulating layer SIN interposed therebetween.

The first conductive pattern layer CP1 and the second conductive pattern layer CP2 may include a single layer or multi-layer metal layer. The first conductive pattern layer CP1 and the second conductive pattern layer CP2 may include at least one of various metal materials including gold (Au), silver (Ag), aluminum (Al), molybdenum (Mo), chromium (Cr), titanium (Ti), nickel (Ni), neodymium (Nd), copper (Cu), and platinum (Pt), or an alloy thereof. According to an embodiment, the first conductive pattern layer CP1 and the second conductive pattern layer CP2 may include at least one of various transparent conductive materials including one of a silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO2), carbon nano tube, and grapheme.

The sensor insulating layer SIN may be disposed on the first conductive pattern layer CP1. The sensor insulating layer SIN may be interposed between the first conductive pattern layer CP1 and the second conductive pattern layer CP2. The protective layer PVX may be disposed on the second conductive pattern layer CP2.

The sensor base layer SBSL may include an inorganic material. The sensor insulating layer SIN may include one or more of an inorganic material and an organic material. According to an embodiment, the protective layer PVX may include one or more of an inorganic material and an organic material. The inorganic material may include one or more of a group of silicon nitride (SiNx), silicon oxide (SiOx), silicon oxynitride (SiOxNy), and aluminum oxide (AlOx). The organic material may include one or more of a group of acrylic resin, epoxy resin, phenol resin, polyamide resin, and polyimide resin. However, the disclosure is not limited thereto.

The sensing electrodes SP may include a cell C and a bridge BRD. The cell C may have the relatively large area, and the bridge BRD may have the relatively small area. Cells C adjacent to each other may be electrically connected by the bridge BRD. The cell C may include a first cell C1 and a second cell C2. The bridge BRD may include a first bridge BRD1 and a second bridge BRD2.

According to an embodiment, the first cell C1 and the second cell C2 may be formed by the second conductive pattern layer CP2. The first bridge BRD1 may be formed by the second conductive pattern layer CP2. A portion of the second bridge BRD2 may be formed by the first conductive pattern layer CP1, and another portion of the second bridge BRD2 may be formed by the second conductive pattern layer CP2.

However, the disclosure is not necessarily limited thereto. For example, the first cell C1 and the second cell C2 may be formed by the first conductive pattern layer CP1. The first bridge BRD1 may be formed by the first conductive pattern layer CP1. A portion of the second bridge BRD2 may be formed by the second conductive pattern layer CP2, and another portion of the second bridge BRD2 may be formed by the first conductive pattern layer CP1.

According to an embodiment, the sensing electrodes SP may have a mesh structure MESH. The cells C and the bridges BRD may have a mesh structure. For example, the second conductive pattern layer CP2 for forming the sensing electrodes SP may be patterned according to a mesh structure. Since the sensing electrodes SP have the mesh structure, a capacitance that may be formed with other electrodes disposed under the cells C may be reduced.

The first sensing electrode SP1 may have a structure in which the first cells C1 of the relatively large area and the first bridge BRD1 of the relatively small area are connected. For example, the first cell C1 may include a (1-1)-th cell C1-1 and a (1-2)-th cell C1-2, and the first bridge BRD1 may electrically connect the (1-1)-th cell C1-1 and the (1-2)-th cell C1-2.

The second sensing electrode SP2 may have a structure in which the second cells C2 of the relatively large area and the second bridge BRD2 of the relatively small area are connected. For example, the second cell C2 may include a (2-1)-th cell C2-1 and a (2-2)-th cell C2-2, and the second bridge BRD2 may electrically connect the (2-1)-th cell C2-1 and the (2-2)-th cell C2-2.

According to an embodiment, the second bridge BRD2 may be electrically connected to the (2-1)-th cell C2-1 through one contact portion CNT and may be electrically connected to the (2-2)-th cell C2-2 through another contact portion CNT. Accordingly, the second bridge BRD2 disposed on a layer different from that of the second cell C2 may electrically connect the (2-1)-th cell C2-1 and the (2-2)-th cell C2-2 through the contact portion CNT. According to an embodiment, the contact portion CNT may pass through the sensor insulating layer SIN.

The first cell C1 and the second cell C2 may have an overall diamond shape (FIG. 8). However, a shape of the first cell C1 and the second cell C2 is not particularly limited thereto. For example, the first cell C1 and the second cell C2 may have an overall quadrangular shape.

The first sensing electrodes SP1 and the second sensing electrodes SP2 may be adjacent to each other with a separation line SEL therebetween. The separation line SEL may be a virtual line disposed in an area between the first sensing electrodes SP1 and the second sensing electrodes SP2. For example, the separation line SEL may be disposed between the (1-1)-th cell C1-1 and the (1-2)-th cell C1-2. The separation line SEL may be disposed between the first bridge BRD1 and the (1-2)-th cell C1-2.

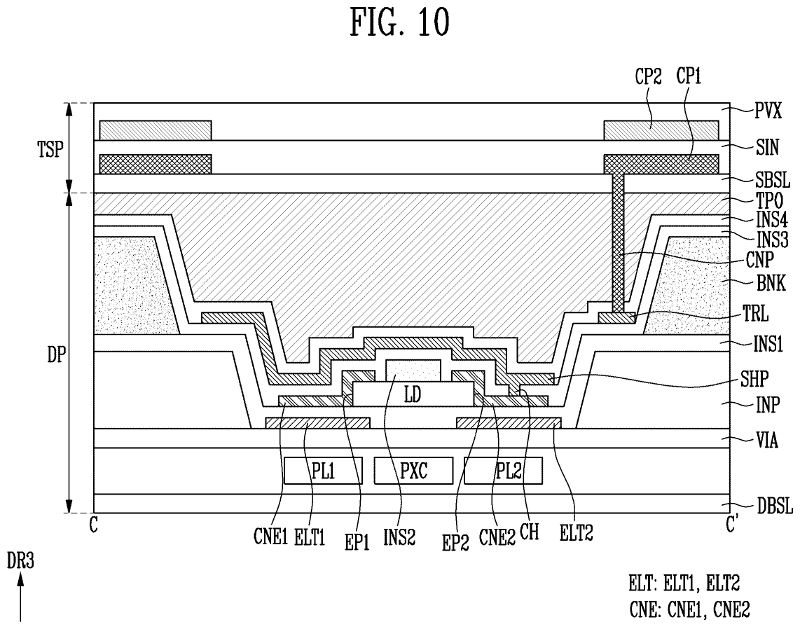

With reference to FIGS. 10 to 12, a cross-sectional structure of the display device DD including the transparent planarization layer TPO and the trace line TRL according to an embodiment is described. A content that may overlap the content described above is briefly described or is not repeated.

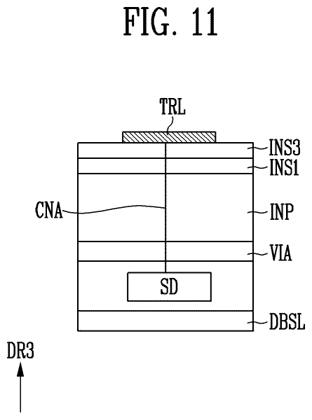

FIG. 10 is a schematic cross-sectional view illustrating the display device DD according to an embodiment. FIG. 10 is a schematic cross-sectional view taken along line C-C′ of FIG. 4. FIG. 11 is a schematic cross-sectional view illustrating an electrical connection structure for the trace line TRL according to an embodiment. FIG. 12 is a schematic cross-sectional view illustrating the display device DD according to an embodiment. FIG. 12 is a schematic cross-sectional view of a structure in which the outer part OUP includes a color filter CF according to an embodiment.

Referring to FIGS. 10 and 11, the display device DD may include the display part DP and the sensor part TSP on the display part DP.

The display part DP may include a pixel circuit PXC and a via layer VIA disposed on the display base layer DBSL. According to an embodiment, the display part DP may further include a first power line PL1 supplying first power and a second power line PL2 supplying second power forming a voltage lower than a voltage of the first power. According to an embodiment, the display part DP may further include a backplane conductive layer SD. The backplane conductive layer SD may be one or more of conductive layers disposed under the light emitting element LD. For example, the backplane conductive layer SD may be a source/drain conductive layer.

The display base layer DBSL may form a base on which the pixel circuit PXC is disposed. The pixel circuit PXC may include circuit elements configured to drive the sub-pixel SPX (or the light emitting element LD). For example, the pixel circuit PXC may include one or more transistors and one or more capacitors. The pixel circuit PXC may be electrically connected to the light emitting element LD through a contact portion at least partially passing through the via layer VIA.

The first and second power lines PL1 and PL2 may be disposed on the display base layer DBSL. The first power line PL1 may be electrically connected to the pixel circuit PXC. The second power line PL2 may be electrically connected to the second electrode ELT2 and/or the second connection electrode CNE2.

The backplane conductive layer SD may form at least a portion of one or more of the pixel circuit PXC, the first power line PL1, and the second power line PL2. For example, a portion of the backplane conductive layer SD may form a source/drain electrode portion of a transistor included in the pixel circuit PXC.

The via layer VIA may be disposed on the pixel circuit PXC. The via layer VIA may be a protective layer. The via layer VIA may include an organic material and may be a planarization layer. At least a portion of a lower contact portion CNA may be formed in the via layer VIA. A contact portion for electrically connecting the first power line PL1, the pixel circuit PXC, and the second power line PL2 to the light emitting element LD may be formed in the via layer VIA. For example, the pixel circuit PXC may be electrically connected to the first electrode ELT1, the first connection electrode CNE1, and the light emitting element LD through a contact portion passing through the via layer VIA. The second power line PL2 may be electrically connected to the second electrode ELT2, the second connection electrode CNE2, and the light emitting element LD through a contact portion passing through the via layer VIA.

The display part DP may include an insulating pattern layer INP, the first and second electrodes ELT1 and ELT2, a first insulating layer INS1, the bank BNK, the light emitting element LD, a second insulating layer INS2, the first and second connection electrodes CNE1 and CNE2, a third insulating layer INS3, the shielding layer SHP, the trace line TRL, a fourth insulating layer INS4, and the transparent planarization layer TPO.

The insulating pattern layer INP may be disposed on the via layer VIA. The insulating pattern layer INP may include first insulating pattern portions and second insulating pattern portions spaced apart from each other. The insulating pattern layer INP may have various shapes according to an embodiment. In an embodiment, the insulating pattern layer INP may protrude in the thickness direction (for example, the third direction DR3) of the display base layer DBSL.

The insulating pattern layer INP may form a step so that the light emitting elements LD may be easily aligned in the emission area EMA. According to an embodiment, the insulating pattern layer INP may be a partition wall. According to an embodiment, the insulating pattern layer INP may include at least one organic material and/or inorganic material. However, the disclosure is not limited to a specific example.

The first and second electrodes ELT1 and ELT2 may be disposed on the via layer VIA and the insulating pattern layer INP. The first electrode ELT1 may receive a first alignment signal and/or the first power through the first power line PL1. The second electrode ELT2 may receive a second alignment signal and/or the second power through the second power line PL2.

The first insulating layer INS1 may be disposed on the first and second electrodes ELT1 and ELT2, and the insulating pattern layer INP. The first insulating layer INS1 may include an inorganic material. For example, the first insulating layer INS1 may include one or more of a group of silicon oxide (SiOx), silicon nitride (SiNx), silicon oxynitride (SiOxNy), aluminum oxide (AlxOy), and titanium oxide (TiOx). However, the disclosure is not limited to the example described above.

The bank BNK may be disposed on the first insulating layer INS1. As described above, the bank BNK may form a space in which the ink including the light emitting element LD may be received.

The light emitting element LD may be disposed (for example, directly disposed) on the first insulating layer INS1 in an area surrounded by the bank BNK. According to an embodiment, the light emitting element LD may emit light based on an electrical signal (for example, an anode signal and a cathode signal) provided from the first connection electrode CNE1 and the second connection electrode CNE2.

The second insulating layer INS2 may be disposed on the light emitting element LD. The second insulating layer INS2 may cover the active layer AL of the light emitting element LD. The second insulating layer INS2 may expose at least a portion of the light emitting element LD. For example, the second insulating layer INS2 may not cover the first end EP1 and the second end EP2 of the light emitting element LD, and thus the first end EP1 and the second end EP2 of the light emitting element LD may be exposed and may be electrically connected to the first connection electrode CNE1 and the second connection electrode CNE2, respectively. According to an embodiment, another portion of the second insulating layer INS2 may be disposed on the bank BNK and the first insulating layer INS1.

When the second insulating layer INS2 is formed on the light emitting elements LD after an alignment of the light emitting elements LD is completed, the light emitting elements LD may be prevented from separating the aligned position.

The second insulating layer INS2 may have a single-layer or multi-layer structure. The second insulating layer INS2 may include at least one of a group of silicon oxide (SiOx), silicon nitride (SiNx), silicon oxynitride (SiOxNy), aluminum nitride (AlNx), aluminum oxide (AlxOy), zirconium oxide (ZrOx), hafnium oxide (HfOx), and titanium oxide (TiOx). However, the disclosure is not limited to the example described above.

The first connection electrode CNE1 and the second connection electrode CNE2 may be disposed on the first insulating layer INS1 and the light emitting element LD. The first connection electrode CNE1 may be electrically connected to the first end EP1 of the light emitting element LD. The second connection electrode CNE2 may be electrically connected to the second end EP2 of the light emitting element LD.

The first connection electrode CNE1 may be electrically connected to the first electrode ELT1, and the second connection electrode CNE2 may be electrically connected to the second electrode ELT2. According to an embodiment, the first connection electrode CNE1 may be electrically connected to the pixel circuit PXC without passing through the first electrode ELT1. The second connection electrode CNE2 may be electrically connected to the second power line PL2 without passing through the second electrode ELT2.

According to an embodiment, the first connection electrode CNE1 and the second connection electrode CNE2 may be patterned at the same time in the same process. However, the disclosure is not limited to the example described above. After one of the first connection electrode CNE1 and the second connection electrode CNE2 is patterned, the remaining electrode may be patterned.

The third insulating layer INS3 may be disposed on the first insulating layer INS1, the second insulating layer INS2, the first and second connection electrodes CEN1 and CNE2, and the bank BNK. The third insulating layer INS3 may include an inorganic material. For example, the third insulating layer INS3 may include at least one of a group of silicon oxide (SiOx), silicon nitride (SiNx), silicon oxynitride (SiOxNy), aluminum oxide (AlxOy), and titanium oxide (TiOx). However, the disclosure is not limited to the example described above.

The third insulating layer INS3 may be disposed between the connection electrode layer CNE and the shielding layer SHP. For example, the third insulating layer INS3 may be disposed between the first connection electrode CNE1 and the shielding layer SHP. The third insulating layer INS3 may be disposed between the second connection electrode CNE2 and the shielding layer SHP.

The third insulating layer INS3 may electrically separate the first connection electrode CNE1 and the shielding layer SHP.

A contact structure CH electrically connecting the second connection electrode CNE2 and the shielding layer SHP may be formed in the third insulating layer INS3. According to an embodiment, the contact structure CH may pass through the third insulating layer INS3. The contact structure CH may include the same conductive material as the shielding layer SHP. The contact structure CH may overlap the second connection electrode CNE2 and the shielding layer SHP in a plan view.

The third insulating layer INS3 may form a base on which the trace line TRL is disposed. For example, the third insulating layer INS3 may contact the trace line TRL.

The shielding layer SHP may be disposed between the light emitting element LD and the transparent planarization layer TPO. The shielding layer SHP may be disposed between the connection electrode layer CNE and the transparent planarization layer TPO. The shielding layer SHP may be disposed on the third insulating layer INS3. The shielding layer SHP may overlap the light emitting element LD in a plan view. The shielding layer SHP may overlap the first and second connection electrodes CNE1 and CNE2 in a plan view.

The shielding layer SHP may reduce a risk that the electrical signal supplied to the light emitting element LD is to be changed by electrical information generated from the sensor part TSP. For example, the shielding layer SHP may reduce a risk that a parasitic capacitance is generated due to electrical flow formed based on a touch event generated in the sensor part TSP.

As described above, the shielding layer SHP may include a transparent conductive material and may transmit light provided by the light emitting element LD.

According to an embodiment, the shielding layer SHP may be electrically connected to the second connection electrode CNE2 through the contact structure CH. According to an embodiment, since the second connection electrode CNE2 may be electrically connected to the second power line PL2, a relatively low potential (or a ground potential) may be formed in the shielding layer SHP. Accordingly, the shielding layer SHP may protect the light emitting element LD more efficiently.

The trace line TRL may be disposed on the third insulating layer INS3. The trace line TRL may be disposed on the insulating pattern layer INP. The trace line TRL may be disposed in an area surrounded by the bank BNK in a plan view. However, the disclosure is not limited thereto.

The trace line TRL may be disposed on the same layer as the shielding layer SHP and may be patterned in the same process. The trace line TRL may include the same material as the shielding layer SHP. Accordingly, the trace line TRL may include a transparent conductive material similar to the shielding layer SHP.

The trace line TRL may be electrically connected to a portion of the sensor part TSP (for example, the first conductive pattern layer CP1) through a contact member CNP at least partially passing through the transparent planarization layer TPO. According to an embodiment, the contact member CNP may pass through the fourth insulating layer INS4, the transparent planarization layer TPO, and a sensor base layer SBSL. Accordingly, an electrical signal supplied to the first and second conductive pattern layers CP1 and CP2 may move through the trace line TRL formed in the display area DA.

According to an embodiment, the trace line TRL may be electrically connected to a conductive pattern layer formed under the via layer VIA through the lower contact portion CNA. For example, the trace line TRL may be electrically connected to the backplane conductive layer SD through the lower contact portion CNA. According to an embodiment, the lower contact portion CNA may pass through the via layer VIA, the insulating pattern layer INP, the first insulating layer INS1, and the second insulating layer INS2. However, the disclosure is not limited thereto. When the trace line TRL and the backplane conductive layer SD are electrically connected to each other, a resistance formed in the trace line TRL may be reduced, a risk that an electrical signal related to a touch input is distorted may be reduced, and thus touch performance may be improved.

The fourth insulating layer INS4 may be disposed on the bank BNK, the third insulating layer INS3, the shielding layer SHP, and the trace line TRL. The fourth insulating layer INS4 may include an inorganic material. For example, the fourth insulating layer INS4 may include at least one of a group of silicon oxide (SiOx), silicon nitride (SiNx), silicon oxynitride (SiOxNy), aluminum oxide (AlxOy), and titanium oxide (TiOx). However, the disclosure is not limited to the example described above.

The transparent planarization layer TPO may be disposed on the fourth insulating layer INS4. The transparent planarization layer TPO may be disposed on the light emitting element LD. The transparent planarization layer TPO may be disposed on the shielding layer SHP.

The transparent planarization layer TPO may be disposed between the light emitting element LD and the sensor part TSP. The transparent planarization layer TPO may cover layers formed under the transparent planarization layer TPO, may have a relatively large thickness, and thus may offset a step generated due to the layers formed thereunder.

The transparent planarization layer TPO may include a transparent organic material. Accordingly, light emitted by the light emitting element LD may pass through the transparent planarization layer TPO. The transparent planarization layer TPO may reduce a risk that a parasitic capacitance is generated in the display part DP by the sensor part TSP.

According to an embodiment, since the transparent planarization layer TPO may have a relatively small refractive index, a low refractive structure may be formed. Therefore, light emission efficiency of the light emitting element LD may be improved, and a luminance characteristic of the display device DD may be improved.

The transparent planarization layer TPO may be formed based on an acryl-based resin composition according to an embodiment, and thus the transparent planarization layer TPO may include an acryl-based resin. The transparent planarization layer TPO may be manufactured by forming the acryl-based resin composition for forming the transparent planarization layer TPO on the display part DP and then curing the acryl-based resin composition. The transparent planarization layer TPO according to an embodiment may be formed to have a sufficient thickness as the transparent planarization layer TPO is manufactured based on the acryl-based resin composition according to an embodiment, and may be patterned based on a photolithography process.

According to an embodiment, the acryl-based resin composition may include an acrylic resin, an acrylic monomer, a photoinitiator, and a solvent.

The acrylic resin and acrylic monomer may be a material mainly included in a solid content of the acryl-based resin composition.

An example of the acrylic resin is not particularly limited. The acrylic resin may be contained in an amount of 6% by weight to 11% by weight based on the entire acryl-based resin composition. According to an embodiment, the acrylic resin may have a weight average molecular weight of 5000 to 25000.

The acrylic monomer may include a multifunctional monomer. The multifunctional monomer may include one or more of cyclic trimethylolpropane formal acrylate, tris(2-hydroxyethyl) isocyanurate triacrylate, and ethoxylated flrorene type diacrylate. The acrylic monomer may be contained in an amount of 2% by weight to 15% by weight based on the entire acryl-based resin composition.

The photoinitiator may be prepared to initiate a reaction of polymerizing the acryl-based resin composition.

The photoinitiator may include one or more of 2,4,6-trimethylbenzoyl-diphenyl-phosphineoxide and 4-dimethylamino) benzophenone. The photoinitiator may be contained in an amount of 2% by weight to 15% by weight based on the entire acryl-based resin composition.

The solvent may include an organic solvent. The solvent may be a material contained in addition to a solid content of the acryl-based resin composition. The solvent may include one or more of methyl 3-methoxypropionate and propylene glycol methyl ether acetate. The solvent may be contained in an amount of 71% by weight to 91% by weight based on the entire acryl-based resin composition.

The sensor part TSP may be disposed on the transparent planarization layer TPO. For example, the sensor base layer SBSL may be disposed on the transparent planarization layer TPO. Accordingly, the sensor part TSP may be manufactured by patterning layers on the display part DP after the display part DP is manufactured. For example, as discussed above, the first and second conductive pattern layers CP1 and CP2 may be patterned, the sensor insulating layer SIN may be formed between the first and second conductive pattern layers CP1 and CP2, and the protective layer PVX may be disposed on the second conductive pattern layer CP2.

Referring to FIG. 12, the outer part OUP may be disposed on the sensor part TSP.

According to an embodiment, the sub-pixel SPX may form a sub-pixel area SPXA where light of one color is provided. The sub-pixel SPX may include first to third sub-pixels SPX1 to SPX3. For example, the first sub-pixel SPX1 may be a red pixel emitting light of red (for example, a first color), the second sub-pixel SPX2 may be a green pixel emitting light of green (for example, a second color), and the third sub-pixel SPX3 may be a blue pixel emitting light of blue (for example, a third color). The red pixel may provide light of a wavelength band of 600 nm to 750 nm. The green pixel may provide light of a wavelength band of 480 nm to 560 nm. The blue pixel may provide light of a wavelength band of 370 nm to 460 nm.

The sub-pixel area SPXA may include a first sub-pixel area SPXA1 where the light of the first color is provided as an area defined by the first sub-pixel SPX1, a second sub-pixel area SPXA2 where the light of the second color is provided as an area defined by the second sub-pixel SPX2, and a third sub-pixel area SPXA3 where the light of the third color is provided as an area defined by the third sub-pixel SPX3.

The light emitting elements LD may include a first light emitting element LD1 included in the first sub-pixel SPX1 and disposed in the first sub-pixel area SPXA1, a second light emitting element LD2 included in the second sub-pixel SPX2 and disposed in the second sub-pixel area SPXA2, and a third light emitting element LD3 included in the third sub-pixel SPX3 and disposed in the third sub-pixel area SPXA3.

The light emitting elements LD may be configured to emit light of different colors for each of the sub-pixels SPX. For example, the first light emitting element LD1 may be configured to emit the light of the first color. The second light emitting element LD2 may be configured to emit the light of the second color. The third light emitting element LD3 may be configured to emit the light of the third color.

According to an embodiment, the outer part OUP may include color filters CF.

The color filters CF may include a first color filter CF1 disposed in the first sub-pixel area SPXA1, a second color filter CF2 disposed in the second sub-pixel area SPXA2, and a third color filter CF3 disposed in the third sub-pixel area SPXA3.

At least a portion of the first color filter CF1 may be disposed in the first sub-pixel area SPXA1. The first color filter CF1 may include a color filter material (for example, dye or pigment) that selectively transmits the light of the first color (for example, red). The light of the first color provided by the first light emitting element LD1 may pass through the first color filter CF1 and may be provided to the outside.

At least a portion of the second color filter CF2 may be disposed in the second sub-pixel area SPXA2. The second color filter CF2 may include a color filter material (for example, dye or pigment) that selectively transmits the light of the second color (for example, green). The light of the second color provided by the second light emitting element LD2 may pass through the second color filter CF2 and may be provided to the outside.

At least a portion of the third color filter CF3 may be disposed in the third sub-pixel area SPXA3. The third color filter CF3 may include a color filter material (for example, dye or pigment) that selectively transmits the light of the third color (for example, blue). The light of the third color provided by the third light emitting element LD3 may pass through the third color filter CF3 and may be provided to the outside.

According to an embodiment, a non-sub-pixel area in which light of one color may not be visible may be formed between the sub-pixel areas SPXA. According to an embodiment, in the non-sub-pixel area, the first color filter CF1, the second color filter CF2, and the third color filter CF3 may overlap in a plan view, and thus a light blocking structure LBS may be formed.

According to an embodiment, the color filter CF may be disposed relatively outside the sensor part TSP based on a display direction (for example, the third direction DR3) of the display device DD, and thus an external light reflection characteristic of the display device DD may be improved.

According to an embodiment, an additional protective layer may be formed on the color filters CF, and a window or a functional film (for example, an anti-reflection film or the like) may be further disposed according to an embodiment.

Hereinafter, an electronic device 1000 including the display device DD in accordance with an embodiment will be described.

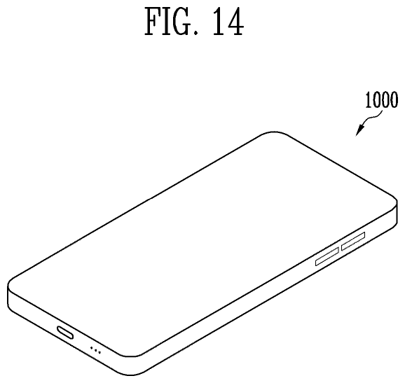

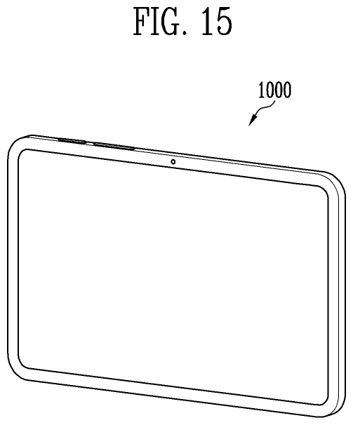

FIG. 13 is a schematic block diagram illustrating an electronic device 1000 including a display device in accordance with an embodiment. FIG. 14 is a schematic diagram illustrating an example where the electronic device 1000 of FIG. 13 is implemented as a smartphone. FIG. 15 is a schematic diagram illustrating an example where the electronic device 1000 of FIG. 13 is implemented as a tablet computer.

Referring to FIGS. 13 to 15, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 14, the electronic device 1000 may be a smartphone. In an embodiment, as illustrated in FIG. 15, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

As described above, although the disclosure has been described with reference to the embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a display part configured to emit light; and
a sensor part disposed on the display part and including sensing electrodes,
wherein the display part comprises:
a first electrode and a second electrode spaced apart from each other;
a light emitting element disposed between the first electrode and the second electrode in a plan view and including a first end and a second end;
a first connection electrode electrically connected to the first end;
a second connection electrode electrically connected to the second end;
a shielding layer overlapping the light emitting element in a plan view; and
a transparent planarization layer disposed on the shielding layer.

2. The display device of claim 1, wherein the shielding layer and the transparent planarization layer are disposed between the light emitting element and the sensor part.

3. The display device of claim 1, wherein the display part further includes a display base layer and a bank protruding in a thickness direction of the display base layer, and
the shielding layer is disposed in an area surrounded by the bank.

4. The display device of claim 1, further comprising:
a display area and a non-display area surrounding at least a portion of the display area,
wherein the shielding layer is disposed entirely in an entire surface of the display area.

5. The display device of claim 1, wherein the shielding layer is electrically connected to the second connection electrode.

6. The display device of claim 5, wherein the display part further includes a first power line supplying first power and a second power line supplying second power forming a voltage lower than a voltage of the first power, and
the second connection electrode is electrically connected to the second power line.

7. The display device of claim 5, wherein the shielding layer is electrically separated from the first connection electrode.

8. The display device of claim 1, wherein the shielding layer includes a transparent conductive material.

9. The display device of claim 1, wherein the transparent planarization layer includes an acryl-based resin.

10. The display device of claim 9, wherein the transparent planarization layer is manufactured based on an acryl-based resin composition,
the acryl-based resin composition includes an acrylic resin, an acrylic monomer, a photoinitiator, and a solvent,
the acrylic resin is contained in an amount of 6% by weight to 11% by weight based on the entire acryl-based resin composition,
the acrylic monomer is contained in an amount of 2% by weight to 15% by weight based on the entire acryl-based resin composition,
the photoinitiator is contained in an amount of 2% by weight to 15% by weight based on the entire acryl-based resin composition, and
the solvent is contained in an amount of 71% by weight to 91% by weight based on the entire acryl-based resin composition.

11. The display device of claim 10, wherein the acrylic resin has a weight average molecular weight of 5000 to 25000,
the acrylic monomer includes one or more of cyclic trimethylolpropane formal acrylate, tris (2-hydroxyethyl)isocyanurate triacrylate, and ethoxylated flrorene type diacrylate,
the photoinitiator includes one or more of 2,4,6-trimethylbenzoyl-diphenyl-phosphineoxide and 4-(dimethylamino)benzophenone, and
the solvent includes one or more of Methyl 3-methoxypropionate and propylene glycol methyl ether acetate.

12. The display device of claim 1, further comprising:
a display area and a non-display area surrounding at least a portion of the display area,
wherein the display part further includes a trace line electrically connected to at least a portion of the sensing electrodes through a contact member of which at least a portion passes through the transparent planarization layer, and
at least a portion of the trace line is disposed in the display area.

13. The display device of claim 12, wherein the shielding layer and the trace line include a same material.

14. The display device of claim 12, wherein the display part further includes a display base layer and a bank protruding in a thickness direction of the display base layer, and
the trace line does not overlap the bank in a plan view.

15. The display device of claim 12, wherein the display part further includes a backplane conductive layer disposed below the light emitting element, and
the backplane conductive layer is electrically connected to the trace line.

16. The display device of claim 1, further comprising:
color filters disposed on the sensor part and transmitting light of one color,
wherein the light emitting element includes an inorganic material.

17. The display device of claim 16, further comprising:
a first sub-pixel area where light of a first color is provided; a second sub-pixel area where light of a second color is provided; and a third sub-pixel area where light of a third color is provided; and
a plurality of light emitting elements including the light emitting element, the plurality of light emitting elements including a first light emitting element disposed in the first sub-pixel area and providing the light of the first color, a second light emitting element disposed in the second sub-pixel area and providing the light of the second color, and a third light emitting element disposed in the third sub-pixel area and providing the light of the third color.

18. A display device comprising:
a display area and a non-display area surrounding at least a portion of the display area;
a display part including:
a first electrode;
a second electrode;
a light emitting element disposed between the first electrode and the second electrode in a plan view; and
a trace line; and
a sensor part disposed on the display part and including sensing electrodes,
wherein at least a portion of the sensing electrodes is electrically connected to the trace line, and
the trace line is disposed in the display area.

19. An electronic device, comprising:
a processor configured to provide input image data;
a display device configured to display an image based on the input image data, the display device including sub-pixel areas; and
a power supply configured to supply power to the display device,
wherein the display device comprises:
a display part configured to emit light; and
a sensor part disposed on the display part and including sensing electrodes,
wherein the display part comprises:
a first electrode and a second electrode spaced apart from each other;
a light emitting element disposed between the first electrode and the second electrode in a plan view and including a first end and a second end;
a first connection electrode electrically connected to the first end;
a second connection electrode electrically connected to the second end;
a shielding layer overlapping the light emitting clement in a plan view; and
a transparent planarization layer disposed on the shielding layer.
